(19) United States
(12) Patent Application Publication
(10) Pub. No.: US 2008/0273369 A1
(43) Pub. Date: Nov. 6, 2008

(54) Integrated Circuit, Memory Module, Method of Operating an Integrated Circuit, and Computing System

(76) Inventors: Michael Angerbauer, Freutsmoos (DE); Michael Markert, Augsburg (DE); Corvin Liaw, Munich (DE)

Correspondence Address: SLATER & MATSIL, L.L.P., 17950 PRESTON ROAD, SUITE 1000, DALLAS, TX, 75252, US

(21) Appl. No.: 11/743,557

(22) Filed: May 2, 2007

(51) Int. Cl. G11C 11/00

(52) U.S. Cl. 365/148

(57) ABSTRACT

According to one embodiment of the present invention, a memory device includes a plurality of resistivity changing memory cells including a current path input terminal and a current path output terminal, respectively, and a plurality of select devices. Each current path output terminal is connected to at least one different current path output terminal via at least one select device.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1a shows a cross-sectional view of a solid electrolyte memory device set to a first memory state;

FIG. 1b shows a cross-sectional view of the solid electrolyte memory device of FIG. 1a set to a second memory state;

FIG. 2 shows a schematic drawing of a memory device according to one embodiment of the present invention;

FIG. 3 shows a schematic drawing of a method of operating a memory device according to one embodiment of the present invention;

FIG. 4 shows a schematic drawing of a method of operating a memory device according to one embodiment of the present invention;

FIG. 5 shows a top view of a memory device according to one embodiment of the present invention;

FIG. 6 shows a top view of a memory device according to one embodiment of the present invention;

FIG. 7 shows a cross-sectional view of the memory device shown in FIG. 6;

FIG. 8 shows a cross-sectional view of the memory device shown in FIG. 6;

FIG. 9 shows a flow chart of a method of operating a memory cell according to one embodiment of the present invention;

FIG. 10A shows a schematic perspective view of a memory module according to one embodiment of the present invention;

FIG. 10B shows a schematic perspective view of a memory module according to one embodiment of the present invention;

FIG. 11 shows a computing system according to one embodiment of the present invention;

FIG. 12 shows a cross-sectional view of a phase changing memory cell;

FIG. 13 shows a schematic drawing of a memory device including resistivity changing memory cells;

FIG. 14A shows a cross-sectional view of a carbon memory cell set to a first switching state;

FIG. 14B shows a cross-sectional view of a carbon memory cell set to a second switching state;

FIG. 15A shows a schematic drawing of a resistivity changing memory cell; and

FIG. 15B shows a schematic drawing of a resistivity changing memory cell.

### DETAILED DESCRIPTION OF ILLUSTRATIVE EMBODIMENTS

According to one embodiment of the present invention, the resistivity changing memory cells are resistive memory cells.

According to one embodiment of the present invention, a memory device is provided which includes a plurality of resistivity changing memory cells including a current path input terminal and a current path output terminal, respectively, a plurality of select devices, and a plurality of bit lines being connected to the memory cells. Each memory cell is arranged such that its current path input terminal is connected to a first bit line, and its current path output terminal is connected to a second bit line, wherein at least one memory cell and at least one select device are connected between the current path output terminal and the second bit line.

According to one embodiment of the present invention, the integrated circuit comprises a plurality of word lines being connected to the plurality of select devices.

According to one embodiment of the present invention, an integrated circuit having a memory device is provided which includes a plurality of resistivity changing memory cells including a current path input terminal and a current path output terminal, respectively, a plurality of select devices, a plurality of bit lines being connected to the memory cells, and a plurality of word lines being connected to the plurality of select devices. Each memory cell is arranged such that its current path input terminal is connected to a first bit line, and its current path output terminal is connected to a second bit line, wherein at least one memory cell and at least one select device are connected between the current path output terminal and the second bit line.

According to one embodiment of the present invention, the current path output terminal of each memory cell is not grounded, but is connected to at least two current path output terminals of other memory cells. The current path which connects the current path output terminals of two different memory cells with each other runs through at least one select device. In order to connect two current path output terminals with each other, all select devices which are part of the current path connecting the two current path output terminals have to be activated, i.e., have to be switched into a conductive state. A current that is generated by a current generator flows, starting from the current generator, via a first bit line to the current path input terminal of the memory cell to be programmed, through the memory cell to be programmed, via corresponding select devices to the current path output terminals of other memory cells, through the other memory cells to respective current path input terminals of the other memory cells, and from the current path input terminals of the other memory cells via a second bit line back to the current generator. The current generated by the current generator may be a programming current used for programming the memory cell, or a current resulting from a programming voltage used for programming the memory cell.

Thus, the programming current flowing into the memory cell to be programmed can be split into different “returning currents” (i.e., each returning current flows via a memory cell, which is different from the memory cell to be programmed, back to the programming current generator). As a consequence, the corresponding select devices have to deal only with a part of the programming current. As a consequence, the dimensions of the select devices can be reduced which means that the shrinking potential of the memory device is increased. In other words, in order to program a memory cell, several select devices are used (the select devices are shared between the memory cells). In this way, it is possible to use several select devices to route the programming current back to the programming current generator which means that the requirements concerning the maximum strength of a current which can be routed through the select device can be reduced.

According to one embodiment of the present invention, the current output terminal of each programmable memory cell is connected to the second bit line via a first current path and a second current path connected in parallel, wherein the first current path runs through a first select device and a first memory cell, and wherein the second current path runs through a second select device and a second memory cell.

According to one embodiment of the present invention, the first memory cell and the second memory cell are neighboring memory cells of the programmable memory cell.

According to one embodiment of the present invention, the first select device and the second select device are directly connected to the programmable memory cell.

According to one embodiment of the present invention, the select devices are arranged as a select device matrix including select device columns and select device rows.

According to one embodiment of the invention, all select devices of a select device row are connected in series with each other.

According to one embodiment of the present invention, all select devices of a select device column are connected to the same word line.

According to one embodiment of the present invention, all select devices of a select device row are connected to different word lines.

According to one embodiment of the present invention, the first bit line and the second bit line, which are assigned to a memory cell, are neighboring bit lines, respectively. However, the invention is not restricted thereto. Between the first bit line and the second bit line, which are assigned to a memory cell, at least one further bit line may be arranged.

According to one embodiment of the present invention, the first bit line and the second bit line, which are assigned to a memory cell, are usable for programming the memory cell and for determining the memory state of the memory cell.

According to one embodiment of the present invention, an integrated circuit having a memory device is provided, the memory device including a plurality of resistivity changing memory cells including a current path input terminal and a current path output terminal, respectively, and a plurality of select devices. Each current path output terminal is connected to at least one different current path output terminal via at least one select device.

According to one embodiment of the present invention, a memory device is provided, the memory device including a plurality of resistivity changing memory cells including a current path input terminal and a current path output terminal, respectively, and a plurality of select devices. Each current path output terminal is connected to at least one different current path output terminal via at least one select device.

According to one embodiment of the present invention, an integrated circuit includes a plurality of resistivity changing memory means including a current path input means and a current path output means, respectively, and a plurality of select means, wherein each current path output means is connected to at least one different current path output means via at least one select means.

According to one embodiment of the present invention, the resistivity changing memory means is a resistivity changing memory cell, for example a MRAM cell, a CBRAM cell, or a PCRAM cell, the current path input means is a current path input terminal, the current path output means is a current path output terminal, and the select means is a select device, for example a select transistor.

According to one embodiment of the present invention, a memory module having at least one integrated circuit or memory device according to one embodiment of the present invention is provided. According to one embodiment of the present invention, the memory module is stackable.

According to one embodiment of the present invention, a method of operating a memory cell of an integrated circuit is provided. The integrated circuit includes a plurality of resistivity changing memory cells including a current path input terminal and a current path output terminal, respectively, a plurality of select devices, and a plurality of bit lines being connected to the memory cells. Each memory cell is arranged such that its current path input terminal is connected to a first bit line, and its current path output terminal is connected to a second bit line, wherein at least one memory cell and at least one select device are connected between the current path output terminal and the second bit line. The method includes activating at least two current paths between the current path output terminal of the memory cell and the second bit line assigned to the memory cell by activating all select devices being part of that current path, and routing a programming current from the first bit line through the memory cell to the second bit line via the at least two activated current paths. Alternatively or additionally, at least one current path is activated between the current output terminal of the memory cell and the second bit line assigned to the memory cell by activating all select devices being part of that current path, and a sensing current is routed from the first bit line through the memory cell to the second bit line via the at least one activated current path.

According to one embodiment of the present invention, the integrated circuit includes a plurality of word lines being connected to the select devices.

According to one embodiment of the present invention, a method of operating a memory cell of a memory device is provided. The memory device includes a plurality of resistivity changing memory cells including a current path input terminal and a current path output terminal, respectively, a plurality of select devices, and a plurality of bit lines being connected to the memory cells. Each memory cell is arranged such that its current path input terminal is connected to a first bit line, and its current path output terminal is connected to a second bit line, wherein at least one memory cell and at least one select device are connected between the current path output terminal and the second bit line. The method includes activating at least two current paths between the current path output terminal of the memory cell and the second bit line assigned to the memory cell by activating all select devices being part of that current path, and routing a programming current from the first bit line through the memory cell to the second bit line via the at least two activated current paths. Alternatively or additionally, at least one current path is activated between the current output terminal of the memory cell and the second bit line assigned to the memory cell by activating all select devices being part of that current path, and a sensing current is routed from the first bit line through the memory cell to the second bit line via the at least one activated current path.

According to one embodiment of the present invention, the integrated circuit includes a plurality of word lines being connected to the select devices.

The present invention further provides a computer program product being configured to perform, when being executed on a computing device, the method of operating a memory cell according to one embodiment of the present invention. Further, the present invention provides a data carrier configured to store a computer program product according to the present invention.

All embodiments of memory devices which have been discussed above can be applied to the embodiments of the operating method according to the present invention.

According to one embodiment of the present invention, the memory cells of the memory device are designed such that they can be programmed using programming currents (i.e., currents are used for forming and erasing conductive paths within the memory cells). According to one embodiment of the present invention, the strengths of the programming currents may range up to 500 μA. According to one embodiment of the present invention, the strengths of the programming currents may range up to 1 mA.

According to one embodiment of the present invention, the memory cells are programmable metallization memory cells, e.g., solid electrolyte memory cells (e.g., conductive bridging random access memory (CBRAM) cells), magneto resistive memory cells (e.g., magneto resistive random access memory (MRAM) cells), phase changing memory cells (e.g., phase changing random access memory (PCRAM) cells), or organic memory cells (e.g., organic random access memory (ORAM) cells). However, the present invention is not restricted thereto. Any type of memory cell which can be programmed with programming currents (or programming voltages) falls under the scope of the present invention.

The type of the select devices may be freely chosen. For example, the selecting devices are transistors.

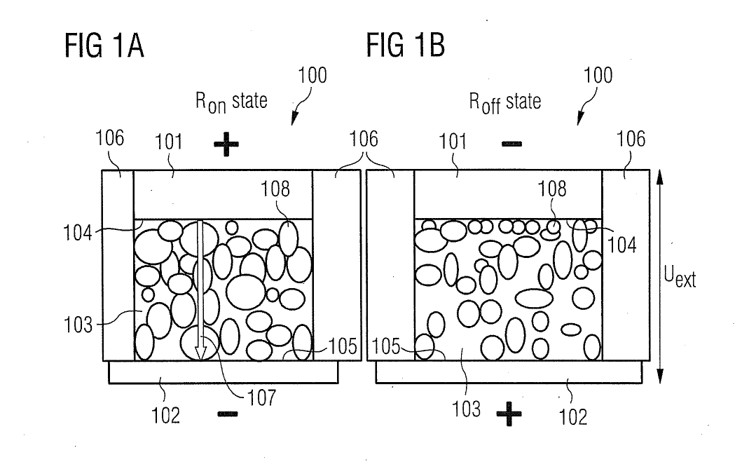

Since the embodiments of the present invention can be applied to programmable metallization cell (PMC) devices (e.g., solid electrolyte devices like conductive bridging random access memory (CBRAM) devices), in the following description, making reference to FIGS. 1A and 1B, a basic principle underlying embodiments of CBRAM devices will be explained.

As shown in FIG. 1A, a CBRAM cell 100 includes a first electrode 101, a second electrode 102, and a solid electrolyte block (in the following description also referred to as ion conductor block) 103 which includes the active material and which is sandwiched between the first electrode 101 and the second electrode 102. This solid electrolyte block 103 can also be shared between a large number of memory cells (not shown). The first electrode 101 contacts a first surface 104 of the ion conductor block 103, and the second electrode 102 contacts a second surface 105 of the ion conductor block 103. The ion conductor block 103 is isolated against its environment by an isolation structure 106. Usually, the first surface 104 is the top surface, and the second surface 105 is the bottom surface of the ion conductor 103. In the same way, generally the first electrode 101 is the top electrode, and the second electrode 102 is the bottom electrode of the CBRAM cell 100. One of the first electrode 101 and the second electrode 102 is a reactive electrode, and the other one is an inert electrode. Here, the first electrode 101 is the reactive electrode, and the second electrode 102 is the inert electrode. In this example, the first electrode 101 includes silver (Ag), the ion conductor block 103 includes silver-doped chalcogenide material, the second electrode 102 includes tungsten (W), and the isolation structure 106 includes SiO₂. The present invention is however not restricted to these materials. For example, the first electrode 101 may alternatively or additionally include copper (Cu) or zinc (Zn), and the ion conductor block 103 may alternatively or additionally include copper-doped chalcogenide material. Further, the second electrode 102 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned compounds, and can also include alloys of the aforementioned metals or materials. The thickness of the ion conductor block 103 may for example range between 5 nm and 500 nm. The thickness of the first electrode 101 may for example range between 10 nm and 100 nm. The thickness of the second electrode 102 may for example range between 5 nm and 500 nm, between 15 nm and 150 nm, or between 25 nm and 100 nm. It is to be understood that the present invention is not restricted to the above-mentioned materials and thicknesses.

In the context of this description, chalcogenide material (ion conductor) is to be understood for example as any compound containing oxygen, sulphur, selenium, germanium and/or tellurium. In accordance with one embodiment of the invention, the ion conducting material is for example a compound, which is made of a chalcogenide and at least one metal from group I or group II of the periodic system, for example arsenic-trisulfide-silver. Alternatively, the chalcogenide material contains germanium-sulfide (GeSₓ), germanium-selenide (GeSeₓ), tungsten oxide (WOₓ), copper sulfide (CuSₓ), or the like. The ion conducting material may be a solid state electrolyte. Furthermore, the ion conducting material can be made of a chalcogenide material containing metal ions, wherein the metal ions can be made of a metal, which is selected from a group consisting of silver, copper and zinc or of a combination or an alloy of these metals.

If a voltage as indicated in FIG. 1A is applied across the ion conductor block 103, a redox reaction is initiated which drives Ag⁺ ions out of the first electrode 101 and into the ion conductor block 103 where they are reduced to Ag, thereby forming Ag rich clusters 108 within the ion conductor block 103. If the voltage applied across the ion conductor block 103 is applied for an enhanced period of time, the size and the number of Ag rich clusters within the ion conductor block 103 is increased to such an extent that a conductive bridge 107 between the first electrode 101 and the second electrode 102 is formed. When a voltage is applied across the ion conductor block 103 as shown in FIG. 1B (inverse voltage compared to the voltage applied in FIG. 1A), a redox reaction is initiated which drives Ag⁺ ions out of the ion conductor block 103 and into the first electrode 101 where they are reduced to Ag. As a consequence, the size and the number of Ag rich clusters 108 within the ion conductor block 103 is reduced, thereby erasing the conductive bridge 107. After having applied the voltage/inverse voltage, the CBRAM cell 100 remains within the corresponding defined switching state even if the voltage/inverse voltage has been removed.

One way to determine the current memory status of a CBRAM cell is to route a sensing current through the CBRAM cell, as an example. The sensing current experiences a high resistance when no conductive bridge 107 exists within the CBRAM cell and experiences a low resistance when a conductive bridge 107 exists within the CBRAM cell. A high resistance may for example represent “0”, whereas a low resistance represents “1”, or vice versa. The memory status detection may also be carried out using sensing voltages.

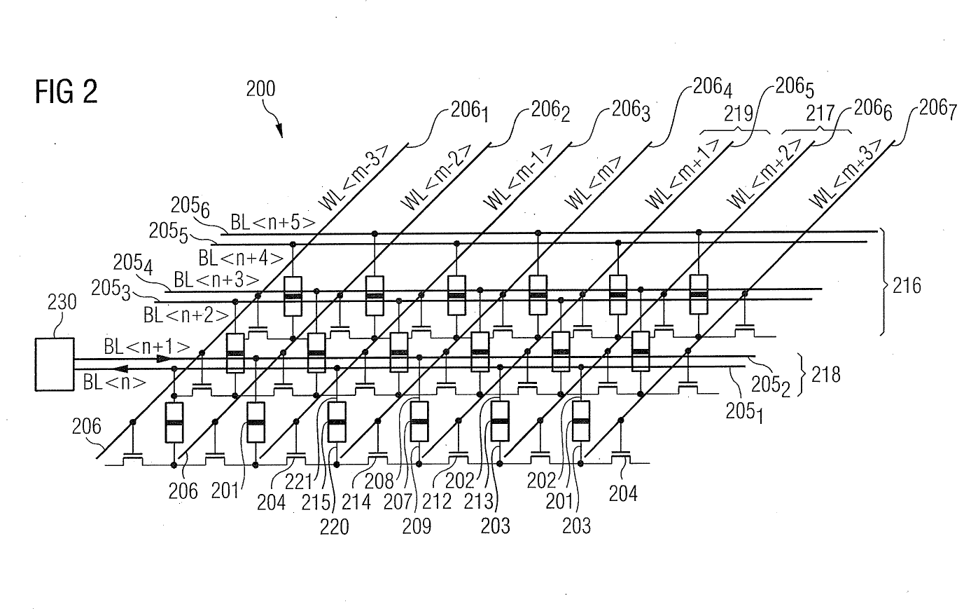

FIG. 2 shows a memory device 200 according to one embodiment of the present invention. The memory device 200 includes a plurality of resistivity changing memory cells 201 which can be programmed using programming currents, wherein each memory cell 201 includes a current path input terminal 202 and a current path output terminal 203. The memory device 200 further includes a plurality of select devices 204, a plurality of bit lines 205₁ to 205₆ being connected to the current path input terminals 202, and a plurality of word lines 206₁ to 206₇ being connected to the plurality of select devices 204.

Each memory cell 201 is arranged such that its current path input terminal 202 is connected to one of a plurality of bit lines 205₁ to 205₆, and its current path output terminal 203 is connected to another one of the plurality of bit lines 205₁ to 205₆. At least one memory cell 201 and at least one select device 204 are connected between the current path output terminal 203 of a memory cell 201 and the second bit line 205 to which the current path output terminal 203 is connected. For example, a memory cell 207 to be programmed includes a current path input terminal 208 and a current path output terminal 209, wherein the current path input terminal 208 is connected to a first bit line 205₂, and the current path output terminal 209 is connected to a second bit line 205₁. The current path input terminal 208 is directly connected to the first bit line 205₂, whereas the current path output terminal 209 is connected to the second bit line 205₁ via a first current path and a second current path. The first current path runs through a first select device 212 and a first memory cell 213. The second current path runs through a second select device 214 and a second memory cell 215. The first memory cell 213 and the second memory cell 215 are neighboring memory cells of the memory cell 207 to be programmed. The first bit line 205₂ and the second bit line 205₁ are neighboring bit lines.

The memory cells 201 are arranged as memory cell matrix including memory cell rows 216 and memory cell columns 217. In the same way, the select devices 204 form a select device matrix including select device rows 218 and select device columns 219. All select devices 204 of one select device row 218 are connected in series. Further, each select device 204 is directly connected to the current path output terminals 209 of two neighboring memory cells 201 of one memory cell row 216. The current path input terminals 202 of the memory cells 201 belonging to the same memory cell row 216 are alternately connected to two different neighboring bit lines 205. All select devices 204 of one select device column 219 are controlled by the same word line 206. All select devices 204 of a select device row 218 are connected to different word lines 206, i.e., each select device 204 of a select device row 218 is controlled by an “own” word line 206.

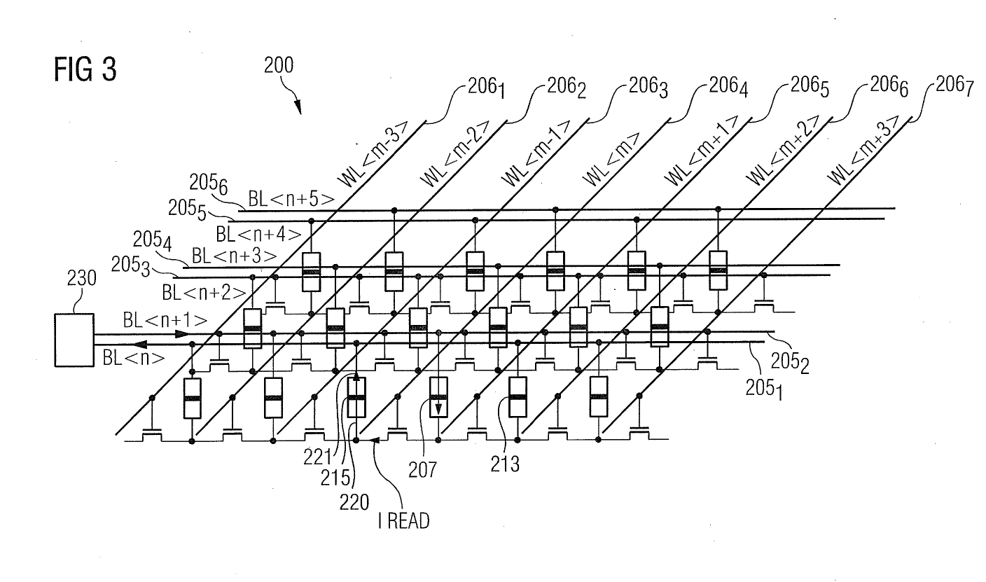

FIG. 3 shows how the memory state of the memory cell 207 of the memory device 200 shown in FIG. 2 is determined. A sensing current is generated by a sensing current generator 230 which is connected to the first bit line 205₂ and the second bit line 205₁. The sensing current flows from the sensing current generator 230 via the first bit line 205₂ to the current path input terminal 209 of the memory cell 207, through the memory cell 207 in order to reach the current path output terminal 208 of the memory cell 207, through the second select device 214 to the current path output terminal 220 of the second memory cell 215, through the second memory cell 215 in order to reach the current path input terminal 221 of the second memory cell 215, and finally back to the sensing current generator 230 via the second bit line 205₁. In order to route the sensing current as described above, a first word line 206₄ is activated, thereby activating the second select device 214, i.e., thereby switching the second select device 214 from a resistive state to a conductive state. Additionally, it may be possible to activate a second word line 206₅, thereby activating the first select device 212. In this way, a part of the sensing current that reaches the current path output terminal 209 is routed via the first select device 212 and the first memory cell 213 to the second bit line 205₁. In this way, the memory state of the memory cell 207 is determined on the basis of the current strengths of the sensing current.

The second select device 214 may be activated in a way that the current strengths of the current flowing through the second memory cell 215 do not exceed a predetermined current strength threshold value. In this way, it is ensured that the sensing current flowing through the second memory cell 215 does not change the memory state of the second memory cell 215.

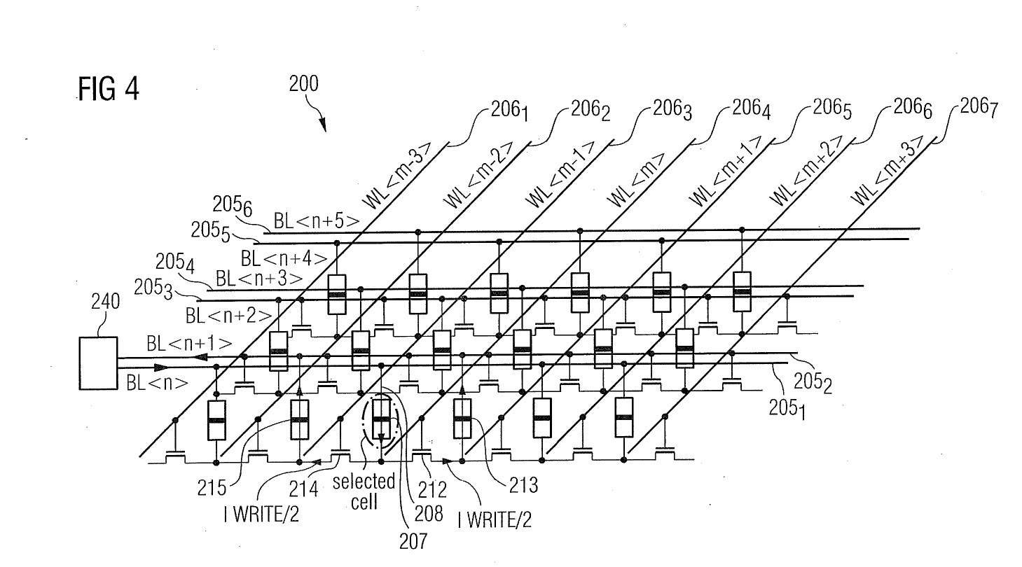

FIG. 4 shows a possibility for how to program the memory cell 207. To do this, the first select device 212 and the second select device 214 are activated (i.e., switched from a resistive state into a conductive state) by activating the first word line 206₃ and the second word line 206₄. In this way, the programming current flows from a programming current generator 240 to the current path input terminal 208 of the memory cell 207 via the second bit line 205₁. It then flows through the memory cell 207 in order to reach the current path output terminal 209 of the memory cell 207. Next, it splits into a first current flowing via the first select device 212 and the first memory cell 213 to the first bit line 205₂ and via the first bit line 205₂ back to the programming current generator 240, and a second current flowing via the second select device 214 and the second memory cell 215 to the first bit line 205₂ and via the first bit line 205₂ back to the programming current generator 240.

Also in this embodiment it may be possible to control the first select device 212 and the second select device 214 such that the currents flowing through the first memory cell 213 and the second memory cell 215 do not change the memory states of these memory cells. Thus, the first select device 212 and the second select device 214 are used as current limiters.

FIG. 5 shows a top view of a memory device 500 according to one embodiment of the present invention. The memory device 500 may for example be the memory device 200 shown in FIGS. 2 to 4.

The memory device 500 includes a plurality of stripe shaped bit lines 205 being arranged parallel to each other, and a plurality of word lines 206 being arranged parallel to each other. The bit lines 205 are arranged perpendicular to the word lines 206. The bit lines 205 contact memory cells 201, wherein two neighboring bit lines 205 contact every second memory cell 201 of the same memory cell row 216. In other words, each bit line 205 is connected to the current path input terminals of two memory cells 201 within an area 501 extending between four neighboring word lines 206.

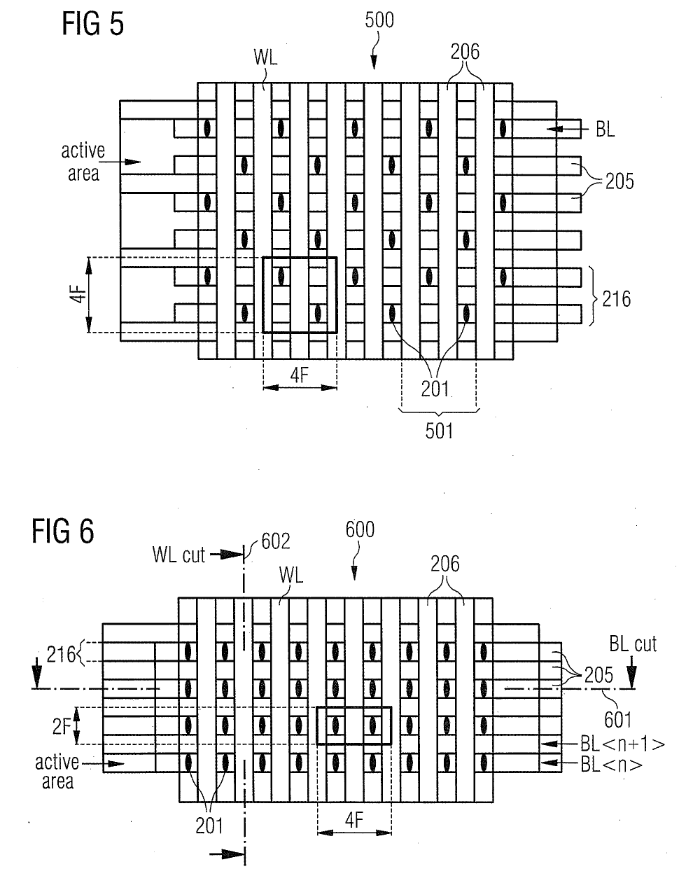

FIG. 6 shows a memory device 600 according to one embodiment of the present invention which may be the memory device 200 shown in FIGS. 2 to 4.

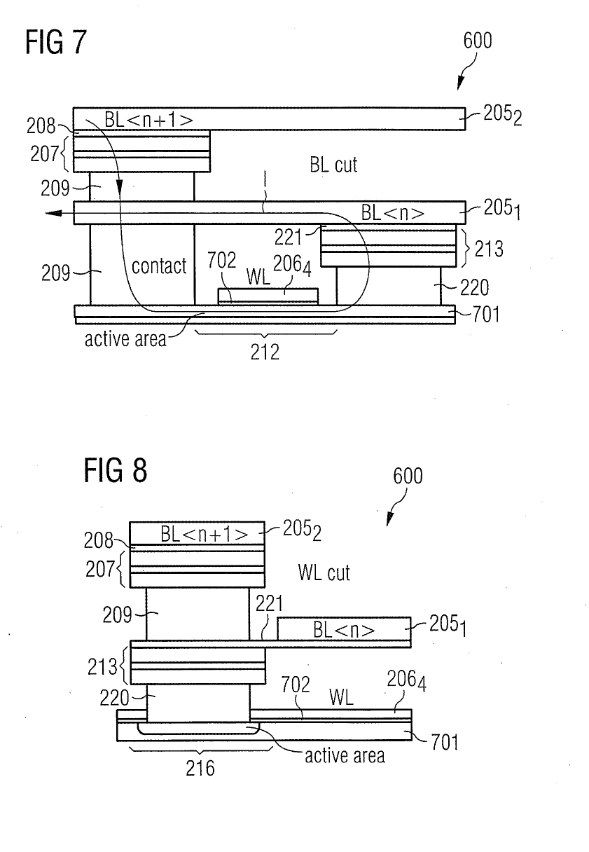

The architecture of the memory device 600 is similar to the architecture of the memory device 500 shown in FIG. 5, except that the number of bit lines 205 is doubled. Further, the memory cells 201 are arranged in different memory cell layers, wherein two neighboring bit lines 205 are contacting memory cells 201 of different memory cell layers. This situation is shown in FIG. 7 (cross-sectional view of the memory device 600 along the line 601) and in FIG. 8 (cross-sectional view of the memory device 600 along the line 602).

As shown in FIG. 7, the memory cell 207 to be programmed and the first memory cell 213, which belong to the same memory cell row 216 and which are neighboring memory cells, are arranged in different memory cell layers (the heights of the memory cell layers are different), wherein the first bit line 205₂, which contacts the memory cell 207 to be programmed, correspondingly has a different height than the second bit line 205₁, which contacts the first memory cell 213. In this embodiment, the memory cells 207, 213 are MRAM memory cells. However, arbitrary resistive memory cells may be used. In order to read out the memory state of the memory cell 207, the first bit line 205₂ and the second bit line 205₁ are selected. Then, a sensing current I is routed via the first bit line 205₂ to the current path input terminal 208 (which may simply be a contacting layer), through the memory cell 207 and the current path output terminal 209 via the first select device 212 to the current path output terminal 220, and then via the first memory cell 213 and the current path input terminal 221 to the second bit line 205₁. In order to do this, the first select device 212 has to be activated by selecting the first word line 206₄ (referring to FIG. 4). The first select device 212 here is a transistor element in which the first word line 206₄ functions as the gate of the transistor. Between the word line and a semiconductor area 701, an isolation layer 702 is provided.

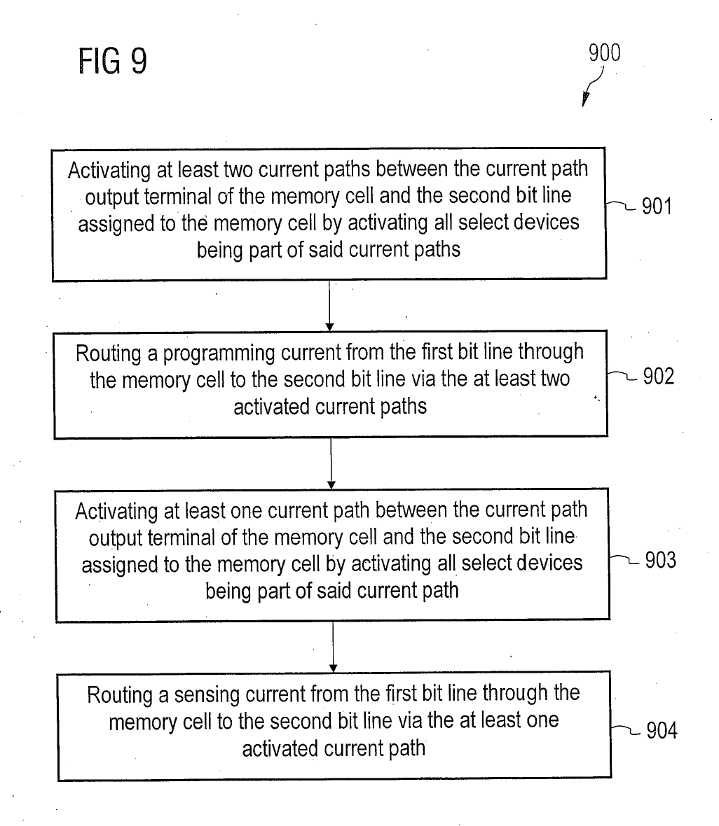

FIG. 9 shows a method of operating a memory cell according to one embodiment of the present invention. In a first process 901, at least two current paths are activated between the current path output terminal of the memory cell and the second bit line assigned to the memory cell by activating all select devices being part of said current paths. In a second process 902, a programming current is routed from the first bit line through the memory cell to the second bit line via the at least two activated current paths. Alternatively or additionally, in a third process 903, at least one current path is activated between the current path output terminal of the memory cell and the second bit line assigned to the memory cell by activating all select devices being part of said current path. Then, in a fourth process 904, a sensing current is routed from the first bit line through the memory cell to the second bit line via the at least one activated current path.

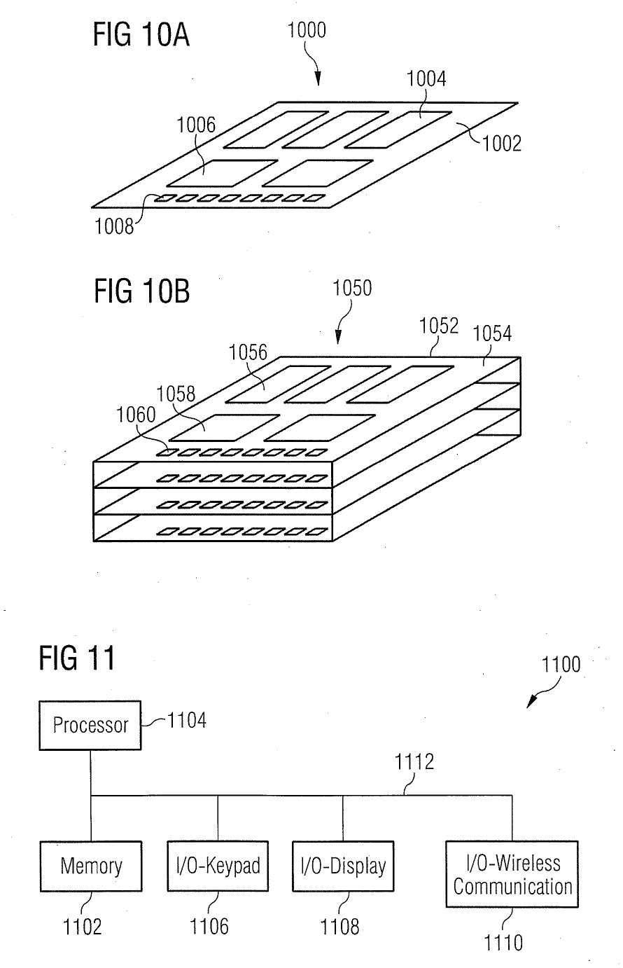

As shown in FIGS. 10A and 10B, in some embodiments, memory devices/integrated circuits such as those described herein may be used in modules. In FIG. 10A, a memory module 1000 is shown, on which one or more memory devices/integrated circuits 1004 are arranged on a substrate 1002. The memory devices/integrated circuits 1004 may include numerous memory cells. The memory module 1000 may also include one or more electronic devices 1006, which may include memory, processing circuitry, control circuitry, addressing circuitry, bus interconnection circuitry, or other circuitry or electronic devices that may be combined on a module with a memory device, such as the memory devices/integrated circuits 1004. Additionally, the memory module 1000 includes multiple electrical connections 1008, which may be used to connect the memory module 1000 to other electronic components, including other modules.

As shown in FIG. 10B, in some embodiments, these modules may be stackable, so as to form a stack 1050. For example, a stackable memory module 1052 may contain one or more integrated circuits/memory devices 1056 arranged on a stackable substrate 1054. The stackable memory module 1052 may also include one or more electronic devices 1058, which may include memory, processing circuitry, control circuitry, addressing circuitry, bus interconnection circuitry, or other circuitry or electronic devices that may be combined on a module with integrated circuits/memory devices, such as the integrated circuits/memory devices 1056. Electrical connections 1060 are used to connect the stackable memory module 1052 with other modules in the stack 1050, or with other electronic devices. Other modules in the stack 1050 may include additional stackable memory modules, similar to the stackable memory module 1052 described above, or other types of stackable modules, such as stackable processing modules, control modules, communication modules, or other modules containing electronic components.

In accordance with some embodiments of the invention, memory devices/integrated circuits as described herein may be used in a variety of applications or systems, such as the illustrative computing system shown in FIG. 11. The computing system 1100 includes memory devices/integrated circuits 1102. The system also includes a processing apparatus 1104, such as a microprocessor or other processing device or controller, as well as input and output apparatus, such as a keypad 1106, display 1108, and/or wireless communication apparatus 1110. The memory devices/integrated circuits 1102, processing apparatus 1104, keypad 1106, display 1108 and wireless communication apparatus 1110 are interconnected by a bus 1112.

The wireless communication apparatus 1110 may have the ability to send and/or receive transmissions over a cellular telephone network, a WiFi wireless network, or other wireless communication network. It will be understood that the various input/output devices shown in FIG. 11 are merely examples. Memory devices including memory cells in accordance with embodiments of the invention may be used in a variety of systems. Alternative systems may include a variety of input and output devices, multiple processors or processing apparatuses, alternative bus configurations, and many other configurations of a computing system. Such systems may be configured for general use, or for special purposes, such as cellular or wireless communication, photography, playing music or other digital media, or any other purpose now known or later conceived to which an electronic device or computing system including memory may be applied.

According to one embodiment of the invention, the resistivity changing memory cells are phase changing memory cells that include a phase changing material. The phase changing material can be switched between at least two different crystallization states (i.e., the phase changing material may adopt at least two different degrees of crystallization), wherein each crystallization state may be used to represent a memory state. When the number of possible crystallization states is two, the crystallization state having a high degree of crystallization is also referred to as a “crystalline state”, whereas the crystallization state having a low degree of crystallization is also referred to as an “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following description that the phase changing material can adopt two crystallization states (an “amorphous state” and a “crystalline state”), however it will be understood that additional intermediate states may also be used.

Phase changing memory cells may change from the amorphous state to the crystalline state (and vice versa) due to temperature changes of the phase changing material. These temperature changes may be caused using different approaches. For example, a current may be driven through the phase changing material (or a voltage may be applied across the phase changing material). Alternatively, a current or a voltage may be fed to a resistive heater which is disposed adjacent to the phase changing material. To determine the memory state of a resistivity changing memory cell, a sensing current may be routed through the phase changing material (or a sensing voltage may be applied across the phase changing material), thereby sensing the resistivity of the resistivity changing memory cell, which represents the memory state of the memory cell.

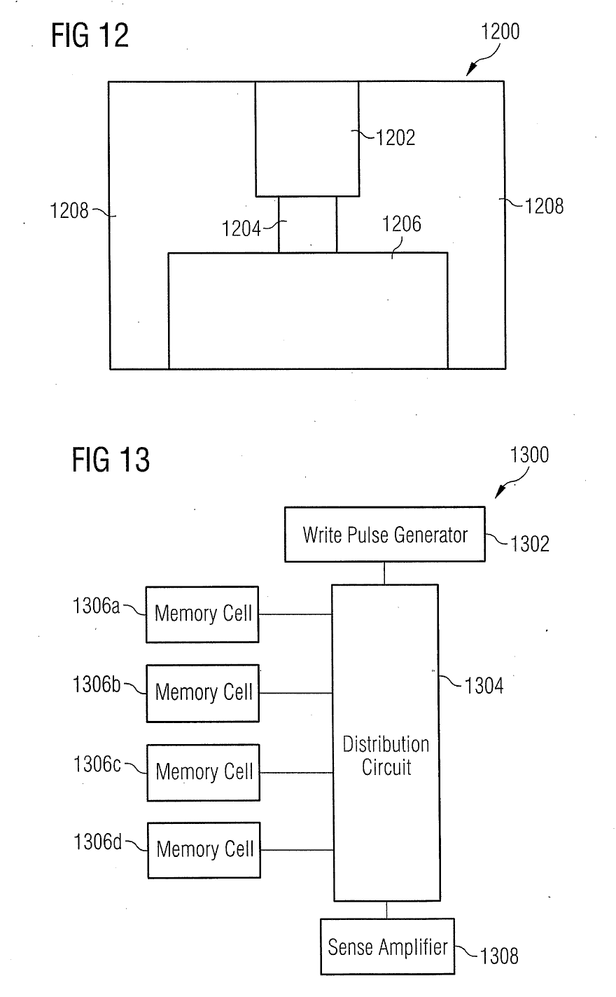

FIG. 12 illustrates a cross-sectional view of an exemplary phase changing memory cell 1200 (active-in-via type). The phase changing memory cell 1200 includes a first electrode 1202, a phase changing material 1204, a second electrode 1206, and an insulating material 1208. The phase changing material 1204 is laterally enclosed by the insulating material 1208. To use the phase changing memory cell, a selection device (not shown), such as a transistor, a diode, or another active device, may be coupled to the first electrode 1202 or to the second electrode 1206 to control the application of a current or a voltage to the phase changing material 1204 via the first electrode 1202 and/or the second electrode 1206. To set the phase changing material 1204 to the crystalline state, a current pulse and/or voltage pulse may be applied to the phase changing material 1204, wherein the pulse parameters are chosen such that the phase changing material 1204 is heated above its crystallization temperature, while keeping the temperature below the melting temperature of the phase changing material 1204. To set the phase changing material 1204 to the amorphous state, a current pulse and/or voltage pulse may be applied to the phase changing material 1204, wherein the pulse parameters are chosen such that the phase changing material 1204 is quickly heated above its melting temperature, and then is quickly cooled.

The phase changing material 1204 may include a variety of materials. According to one embodiment, the phase changing material 1204 may include or consist of a chalcogenide alloy that includes one or more elements from group VI of the periodic table. According to another embodiment, the phase changing material 1204 may include or consist of a chalcogenide compound material, such as GeSbTe, SbTe, GeTe or AgInSbTe. According to a further embodiment, the phase changing material 1204 may include or consist of chalcogen free material, such as GeSb, GaSb, InSb, or GeGaInSb. According to still another embodiment, the phase changing material 1204 may include or consist of any suitable material including one or more of the elements Ge, Sb, Te, Ga, Bi, Pb, Sn, Si, P, O, As, In, Se, and S.

According to one embodiment, at least one of the first electrode 1202 and the second electrode 1206 may include or consist of Ti, V, Cr, Zr, Nb, Mo, Hf, Ta, W, or mixtures or alloys thereof. According to another embodiment, at least one of the first electrode 1202 and the second electrode 1206 may include or consist of Ti, V, Cr, Zr, Nb, Mo, Hf, Ta, W and two or more elements selected from the group consisting of B, C, N, O, Al, Si, P, S, and/or mixtures and alloys thereof. Examples of such materials include TiCN, TiAlN, TiSiN, W—Al₂O₃ and Cr—Al₂O₃.

FIG. 13 illustrates a block diagram of a memory device 1300 including a write pulse generator 1302, a distribution circuit 1304, phase changing memory cells 1306a, 1306b, 1306c, 1306d (for example phase changing memory cells 200 as shown in FIG. 2), and a sense amplifier 1308. According to one embodiment, the write pulse generator 1302 generates current pulses or voltage pulses that are supplied to the phase changing memory cells 1306a, 1306b, 1306c, 1306d via the distribution circuit 1304, thereby programming the memory states of the phase changing memory cells 1306a, 1306b, 1306c, 1306d. According to one embodiment, the distribution circuit 1304 includes a plurality of transistors that supply direct current pulses or direct voltage pulses to the phase changing memory cells 1306a, 1306b, 1306c, 1306d or to heaters being disposed adjacent to the phase changing memory cells 1306a, 1306b, 1306c, 1306d.

As already indicated, the phase changing material of the phase changing memory cells 1306a, 1306b, 1306c, 1306d may be changed from the amorphous state to the crystalline state (or vice versa) under the influence of a temperature change. More generally, the phase changing material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 1308 is capable of determining the memory state of one of the phase changing memory cells 1306a, 1306b, 1306c, or 1306d depending on the resistance of the phase changing material.

To achieve high memory densities, the phase changing memory cells 1306a, 1306b, 1306c, 1306d may be capable of storing multiple bits of data, i.e., the phase changing material may be programmed to more than two resistance values. For example, if a phase changing memory cell 1306a, 1306b, 1306c, 1306d is programmed to one of three possible resistance levels, 1.5 bits of data per memory cell can be stored. If the phase changing memory cell is programmed to one of four possible resistance levels, two bits of data per memory cell can be stored, and so on.

The embodiment shown in FIG. 13 may also be applied in a similar manner to other types of resistivity changing memory cells like programmable metallization cells (PMCs), magneto-resistive memory cells (e.g., MRAMs) or organic memory cells (e.g. ORAMs).

Another type of resistivity changing memory cell may be formed using carbon as a resistivity changing material. Generally, amorphous carbon that is rich is sp³-hybridized carbon (i.e., tetrahedrally bonded carbon) has a high resistivity, while amorphous carbon that is rich in sp²-hybridized carbon (i.e., trigonally bonded carbon) has a low resistivity. This difference in resistivity can be used in a resistivity changing memory cell.

In one embodiment, a carbon memory cell may be formed in a manner similar to that described above with reference to phase changing memory cells. A temperature-induced change between an sp³-rich state and an sp²-rich state may be used to change the resistivity of an amorphous carbon material. These differing resistivities may be used to represent different memory states. For example, a high resistance sp³-rich state can be used to represent a “0”, and a low resistance sp²-rich state can be used to represent a “1”. It will be understood that intermediate resistance states may be used to represent multiple bits, as discussed above.

Generally, in this type of carbon memory cell, application of a first temperature causes a change of high resistivity sp³-rich amorphous carbon to relatively low resistivity sp²-rich amorphous carbon. This conversion can be reversed by application of a second temperature, which is typically higher than the first temperature. As discussed above, these temperatures may be provided, for example, by applying a current and/or voltage pulse to the carbon material. Alternatively, the temperatures can be provided by using a resistive heater that is disposed adjacent to the carbon material.

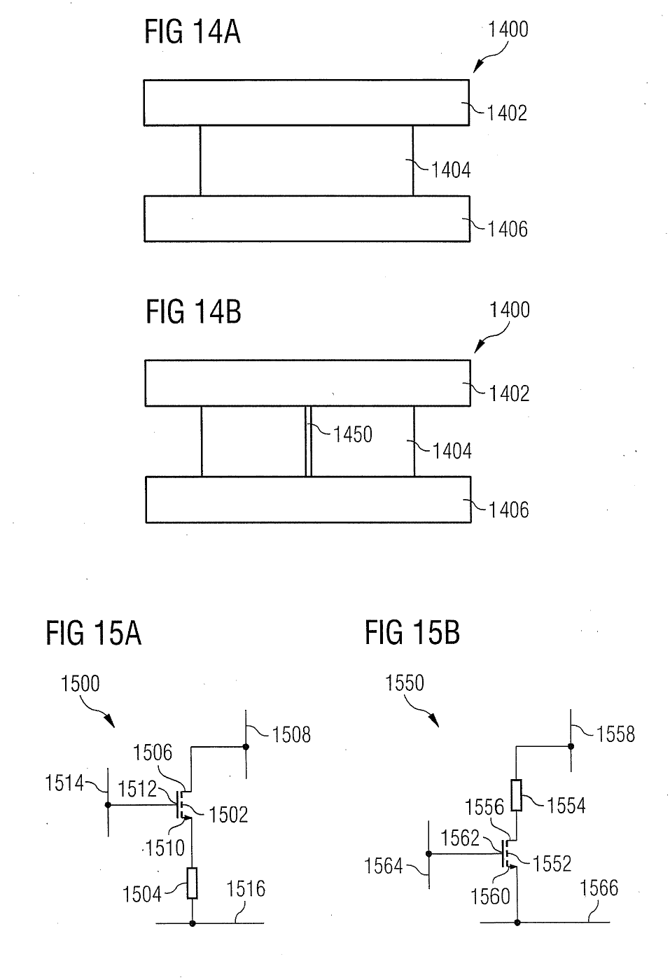

Another way in which resistivity changes in amorphous carbon can be used to store information is by field-strength induced growth of a conductive path in an insulating amorphous carbon film. For example, applying voltage or current pulses may cause the formation of a conductive sp² filament in insulating sp³-rich amorphous carbon. The operation of this type of resistive carbon memory is illustrated in FIGS. 14A and 14B.

FIG. 14A shows a carbon memory cell 1400 that includes a top contact 1402, a carbon storage layer 1404 including an insulating amorphous carbon material rich in sp³-hybridized carbon atoms, and a bottom contact 1406. As shown in FIG. 14B, by forcing a current (or voltage) through the carbon storage layer 1404, an sp² filament 1450 can be formed in the sp³-rich carbon storage layer 1404, changing the resistivity of the memory cell. Application of a current (or voltage) pulse with higher energy (or, in some embodiments, reversed polarity) may destroy the sp² filament 1450, increasing the resistance of the carbon storage layer 1404. As discussed above, these changes in the resistance of the carbon storage layer 1404 can be used to store information, with, for example, a high resistance state representing a “0” and a low resistance state representing a “1”. Additionally, in some embodiments, intermediate degrees of filament formation or formation of multiple filaments in the sp³-rich carbon film may be used to provide multiple varying resistivity levels, which may be used to represent multiple bits of information in a carbon memory cell. In some embodiments, alternating layers of sp³-rich carbon and sp²-rich carbon may be used to enhance the formation of conductive filaments through the sp³-rich layers, reducing the current and/or voltage that may be used to write a value to this type of carbon memory.

Resistivity changing memory cells, such as the phase changing memory cells and carbon memory cells described above, may include a transistor, a diode, or another active component for selecting the memory cell. FIG. 15A shows a schematic representation of such a memory cell that uses a resistivity changing memory element. The memory cell 1500 includes a select transistor 1502 and a resistivity changing memory element 1504. The select transistor 1502 includes a source 1506 that is connected to a bit line 1508, a drain 1510 that is connected to the memory element 1504, and a gate 1512 that is connected to a word line 1514. The resistivity changing memory element 1504 also is connected to a common line 1516, which may be connected to ground, or to other circuitry, such as circuitry (not shown) for determining the resistance of the memory cell 1500, for use in reading. Alternatively, in some configurations, circuitry (not shown) for determining the state of the memory cell 1500 during reading may be connected to the bit line 1508. It should be noted that as used herein the terms connected and coupled are intended to include both direct and indirect connection and coupling, respectively.

To write to the memory cell 1500, the word line 1514 is used to select the memory cell 1500, and a current (or voltage) pulse on the bit line 1508 is applied to the resistivity changing memory element 1504, changing the resistance of the resistivity changing memory element 1504. Similarly, when reading the memory cell 1500, the word line 1514 is used to select the memory cell 1500, and the bit line 1508 is used to apply a reading voltage (or current) across the resistivity changing memory element 1504 to measure the resistance of the resistivity changing memory element 1504.

The memory cell 1500 may be referred to as a 1T1J cell, because it uses one transistor and one memory junction (the resistivity changing memory element 1504). Typically, a memory device will include an array of many such cells. It will be understood that other configurations for a 1T1J memory cell, or configurations other than a 1T1J configuration, may be used with a resistivity changing memory element. For example, in FIG. 15B, an alternative arrangement for a 1T1J memory cell 1550 is shown, in which a select transistor 1552 and a resistivity changing memory element 1554 have been repositioned with respect to the configuration shown in FIG. 15A. In this alternative configuration, the resistivity changing memory element 1554 is connected to a bit line 1558 and to a source 1556 of the select transistor 1552. A drain 1560 of the select transistor 1552 is connected to a common line 1566, which may be connected to ground, or to other circuitry (not shown), as discussed above. A gate 1562 of the select transistor 1552 is controlled by a word line 1564.

In the following description, further aspects of the present invention will be explained.

According to one embodiment of the present invention, large cell areas are avoided. Further, the supply voltages of the memory chip are decreased.

Future MRAM (magneto-resistive random access memory) write concepts may require a large write current to be driven through an access transistor. According to one embodiment of the present invention, the write currents through the array access transistor may range up to 500 μA, even up to 1 mA (MRAM). Also future PCRAM (phase changing random access memory) write concepts may require high write currents. According to one embodiment of the present invention, the write currents through the array access transistor may range up to 300 μA-400 μA (PCRAM). The result is that the array access transistor has to show a low resistance and a large width. A large array transistor width causes a die area penalty. Further, the cell size is very large with a usual FET. In addition, the ON-resistance of the array access transistor causes a large voltage drop over the array access transistor. As a consequence, the supply voltage of the memory chip will increase. This causes many challenges to the periphery circuits (charge pumps, etc.). The same problems can be found in many types of non-volatile resistive memories.

FIG. 2 also shows an embodiment of an array architecture usable for MRAM cells, for example. The select devices, which are implemented as field effect transistors, have three terminals. One terminal is connected to a word line for switching between the high resistive OFF state and the low resistive ON state of the select device. Each of the two other terminals is connected to a resistive memory cell, in the example of FIG. 2 to a MRAM cell.

One cell unit contains three select devices. The sharing of the select device terminals which are connected to a resistive memory cell enables the reduction of the die area in the array. The select transistor may for example be a field effect transistor, a finFET transistor or a bipolar transistor.

Different variations in the layout are possible:
1) 10 F² per bit cell.

If large currents are driven through the select device, and the metal levels are limited, a 10 F² per bit cell is possible. In the embodiment shown in FIG. 2, the select device is implemented as a field effect transistor. The active area of the transistor is determined by the two on pitch metal bit lines. The metal bit lines are in the same metal level, here in metal level 1. This means that the pitch in the bit line direction is 4 F with a 3 F wide field effect transistor. The pitch in the word line direction is also 4 F because two select device transistors are always shared with the next cell. A cell unit size of 16 F² may be used. The two resistive memory cells can only store three different values (1.5 bits). These values are determined by the following cell states. Both cells are in the high resistive state; one cell is in the high resistive state, and the other is in the low resistive state; or both cells are in the low resistive state. A normalized cell size of 10.7 F per bit may be used. This is a larger cell area than the cell area used in conventional array architectures. The advantages of this array include that the requirements to the select device are not as high as in conventional array architectures. Another advantage is that the select device can be designed wider (3 F channel width for a FET) which means that the ON resistance will be lower. This results in lower supply voltages for the memory. As a consequence, the periphery circuits are much smaller (charge pumps, etc.).
2) 4 F² per bit cell.

If the cells are arranged in a stacked manner, a 4 F² per bit cell is possible. The width of the select device is reduced to one F due to the different metal levels of the bit lines. The cell size in the word line direction is equal to the 10 F per bit cell (4 F). If the memory cells are also stacked, different memory cells with different resistances can be processed. This may for example be possible in MRAM cells due to different magnetic tunnel junction thicknesses.

According to one embodiment of the present invention, during a read cycle, the word line, which neighboured cell should be read out, opens the select device. All other select devices are closed. Between the bit lines of the selected resistive cells a voltage potential difference is applied. This potential difference generates a cell resistance dependent current on the bit lines. This current can be sensed.

According to one embodiment of the present invention, during a write cycle, two write concepts may be adopted: 1.) a heat current may be routed through the cell followed by a field current on the bit line (like thermal select); and 2.) only one current may be routed through the cell (like spin torque or thermal assisted spin torque).

According to one embodiment of the present invention, if a current has to be routed through a selected cell, the two word lines being closest to the selected cell open the two select devices which are connected to the selected cell. The write current is applied on a bit line, and the write current flows back over the stacked bit line. The benefit is that the two select transistors that are connected in series with a cell are connected parallel on the next bit line. So the effective resistance of the select device is halved.

As used herein, the terms “connected” and “coupled” are intended to include both direct and indirect connection and coupling, respectively.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined solely by the claims appended hereto.

What is claimed is:

1. An integrated circuit comprising:
a plurality of resistivity changing memory cells, each comprising a current path input terminal and a current path output terminal;
a plurality of select devices; and
a plurality of bit lines being coupled to the plurality of resistivity changing memory cells;
each resistivity changing memory cell being arranged such that its current path input terminal is coupled to a first bit line, and its current path output terminal is coupled to a second bit line, wherein at least one resistivity changing memory cell and at least one select device are coupled between the current path output terminal and the second bit line.

2. The integrated circuit according to claim 1,
wherein the current path output terminal of each resistivity changing memory cell is connected to the second bit line via a first current path and a second current path connected in parallel,
wherein the first current path runs through a first select device and a first resistivity changing memory cell, and
wherein the second current path runs through a second select device and a second resistivity changing memory cell.

3. The integrated circuit according to claim 2, wherein the first resistivity changing memory cell and the second resistivity changing memory cell are neighboring memory cells of the resistivity changing memory cell.

4. The integrated circuit according to claim 2, wherein the first select device and the second select device are directly connected to the resistivity changing memory cell.

5. The integrated circuit according to claim 1, wherein the plurality of select devices are arranged as a select device matrix comprising select device columns and select device rows.

6. The integrated circuit according to claim 5, wherein all select devices of a select device row are coupled in series with each other.

7. The integrated circuit according to claim 5, further comprising a plurality of word lines being coupled to the plurality of select devices, wherein all select devices of a select device column are coupled to the same word line.

8. The integrated circuit according to claim 5, further comprising a plurality of word lines being coupled to the plurality of select devices, wherein all select devices of a select device row are coupled to different word lines.

9. The integrated circuit according to claim 1, wherein the first bit line and the second bit line being assigned to a resistivity changing memory cell are neighboring bit lines.

10. The integrated circuit according to claim 1, wherein the first bit line and the second bit line being assigned to a resistivity changing memory cell are usable for programming the resistivity changing memory cell and for determining the memory state of the resistivity changing memory cell.

11. The integrated circuit according to claim 2, wherein the first select device is arranged or is controllable such that the current flowing through the first resistivity changing memory cell is limited to a particular first current value, and the second select device is arranged or is controllable such that the current flowing through the second resistivity changing memory cell is limited to a particular second current value.

12. The integrated circuit according to claim 11, wherein the first current value and the second current value are chosen such that the currents flowing through the first resistivity changing memory cell and the second resistivity changing memory cell do not change the memory states of the first resistivity changing memory cell and the second resistivity changing memory cell.

13. The integrated circuit according to claim 1, further comprising a plurality of word lines coupled to the plurality of select devices, the plurality of bit lines being arranged parallel to each other, the plurality of word lines being arranged parallel to each other, and the plurality of bit lines being arranged perpendicular to the plurality of word lines.

14. The integrated circuit according to claim 13, wherein each bit line is coupled to the current path input terminals of two resistivity changing memory cells within an area extending between four neighboring word lines.

15. The integrated circuit according to claim 13, wherein the resistivity changing memory cells are arranged in different memory cell layers, and wherein neighboring bit lines are contacting resistivity changing memory cells of different memory cell layers.

16. The integrated circuit according to claim 15, wherein neighboring bit lines have different heights.

17. The integrated circuit according to claim 16, wherein the electrical properties of the resistivity changing memory cells of different memory cell layers are different.

18. The integrated circuit according to claim 1, wherein the resistivity changing memory cells are programmable metallization memory cells.

19. The integrated circuit according to claim 18, wherein the programmable metallization memory cells are solid electrolyte memory cells.

20. The integrated circuit according to claim 1, wherein the resistivity changing memory cells are phase changing memory cells.

21. The integrated circuit according to claim 1, wherein the resistivity changing memory cells are carbon memory cells.

22. An integrated circuit comprising:
a plurality of resistivity changing memory cells, each comprising a current path input terminal and a current path output terminal; and
a plurality of select devices,
wherein each current path output terminal is coupled to at least one different current path output terminal via at least one select device.

23. An integrated circuit comprising:
a plurality of resistivity changing memory means, each comprising a current path input means and a current path output means; and
a plurality of select means,
wherein each current path output means is connected to at least one different current path output means via at least one select means.

24. A memory module comprising a memory device, the memory device comprising:
a plurality of resistivity changing memory cells, each comprising a current path input terminal and a current path output terminal; and
a plurality of select devices,
wherein each current path output terminal is connected to at least one different current path output terminal via at least one select device.

25. The memory module according to claim 24, wherein the memory module is stackable.

26. A method of operating a memory cell of an integrated circuit, the method comprising:
providing an integrated circuit comprising:
a plurality of resistivity changing memory cells, each comprising a current path input terminal and a current path output terminal;
a plurality of select devices; and
a plurality of bit lines being coupled to the plurality of resistivity changing memory cells,
each resistivity changing memory cell being arranged such that its current path input terminal is connected to a first bit line, and its current path output terminal is connected to a second bit line, wherein at least one resistivity changing memory cell and at least one select device are connected between the current path output terminal and the second bit line,
activating at least two current paths between the current output terminal of the resistivity changing memory cell and the second bit line assigned to the resistivity changing memory cell by activating all select devices being part of said current paths,
routing a programming current from the first bit line through the resistivity changing memory cell to the second bit line via the at least two activated current paths, and/or activating at least one current path between the current output terminal of the resistivity changing memory cell and the second bit line assigned to the resistivity changing memory cell by activating all select devices being part of said current path, and
routing a sensing current from the first bit line through the resistivity changing memory cell to the second bit line via the at least one activated current path.

27. The method according to claim 26,
wherein the current output terminal of each resistivity changing memory cell is coupled to the second bit line by activating a first current path and a second current path coupled in parallel,
wherein the first current path runs through a first select device and a first resistivity changing memory cell, and
wherein the second current path runs through a second select device and a second resistivity changing memory cell.

28. The method according to claim 27, wherein the first resistivity changing memory cell and the second resistivity changing memory cell are neighboring memory cells of the programmable resistivity changing memory cell.

29. The method according to claim 27, wherein the first select device and the second select device are directly connected to the programmable resistivity changing memory cell.

30. The method according to claim 26, wherein the select devices are arranged as a select device matrix comprising select device columns and select device rows.

31. The method according to claim 30, wherein all select devices of a select device row are coupled in series with each other.

32. The method according to claim 31, comprising a plurality of word lines coupled to the select devices, wherein all select devices of a select device column are coupled to the same word line.

33. The method according to claim 31, comprising a plurality of word lines coupled to the select devices, wherein all select devices of a select device row are coupled to different word lines.

34. The method according to claim 26, wherein the first bit line and the second bit line being assigned to a resistivity changing memory cell are neighboring bit lines.

35. The method according to claim 27, wherein the first select device is controlled such that the current flowing through the first resistivity changing memory cell is limited to a particular first current value, and the second select device is controlled such that the current flowing through the second resistivity changing memory cell is limited to a particular second current value.

36. The method according to claim 35, wherein the first current value and the second current value are chosen such that the currents flowing through the first resistivity changing memory cell and the second resistivity changing memory cell do not change the memory states of the first resistivity changing memory cell and the second resistivity changing memory cell.

37. The method according to claim 26, wherein the integrated circuit comprises a plurality of word lines being coupled to the plurality of select devices, the bit lines being arranged parallel to each other, the word lines being arranged parallel to each other, and the bit lines being arranged perpendicular to the word lines.

38. The method according to claim 37, wherein each bit line is connected to the current path input terminals of two resistivity changing memory cells within an area extending between four neighboring word lines.

39. The method according to claim 37, wherein each bit line is connected to the current path input terminals of one resistivity changing memory cell within an area extending between two neighboring word lines.

40. The method according to claim 26, wherein the resistivity changing memory cells are arranged in different memory cell layers, and wherein two neighboring bit lines are contacting resistivity changing memory cells of different memory cell layers.

41. The method according to claim 40, wherein the electrical properties of the resistivity changing memory cells of different memory cell layers are different.

42. A computing system comprising:
an input apparatus;
an output apparatus;
a processing apparatus; and
a memory device, the memory device comprising:
a plurality of resistivity changing memory cells, each comprising a current path input terminal and a current path output terminal;
a plurality of select devices; and
a plurality of bit lines being connected to the resistivity changing memory cells,
each resistivity changing memory cell being arranged such that its current path input terminal is connected to a first bit line, and its current path output terminal is connected to a second bit line, wherein at least one resistivity changing memory cell and at least one select device are connected between the current path output terminal and the second bit line.

43. The computing system according to claim 42, wherein at least one of the input apparatus and the output apparatus comprises a wireless communication apparatus.
